(19) United States
(12) Patent Application Publication
(10) Pub. No.: US 2009/0230461 A1
(43) Pub. Date: Sep. 17, 2009

(54) Cell device and cell string for high density NAND flash memory

(75) Inventor: Jong-Ho Lee, Daegu (KR)

Correspondence Address: THE NATH LAW GROUP, 112 South West Street, Alexandria, VA, 22314, US

(73) Assignee: KYUNGPOOK NATIONAL UNIVERTISY INDUSTRY-ACADEMIC COOPERATION FOUNDATION, Daegu (KR)

(21) Appl. No.: 12/320,620

(22) Filed: Jan. 30, 2009

(30) Foreign Application Priority Data
Feb. 4, 2008 (KR) 10-2008-0011337

(51) Int. Cl. H01L 29/792

(52) U.S. Cl. 257/325; 977/943; 257/E29.309

(57) ABSTRACT

The invention relates a cell device and a cell string for high density flash memory. The cell string includes a plurality of cell devices and switching devices connected to ends of the plurality of cell devices. The cell device includes a semiconductor substrate, an insulating film, a charge storage node composed of nano-sized dots, a control insulating film and a control electrode which are sequentially formed on the semiconductor substrate, without source/drain regions. In the cell string, the silicon substrate enables easy formation of an inversion layer acting as the source/drain regions. The switching device does not include a source or drain region at a side connected to an adjacent cell device but includes a source or drain region at the side opposite to the side connected to the adjacent cell device. The invention improves miniaturizability and performance of cell devices for NAND flash memory, and induces an inversion layer by using a fringing electric field generated from the control electrode and the charge storage node, thus allowing for electrical connection between cells or between cell strings.

### CROSS REFERENCE TO RELATED APPLICATION

This application claims the benefit of Korean Patent Application No. 10-2008-0011337, filed Feb. 4, 2008, entitled “High density NAND flash memory cell device and cell string”, which is hereby incorporated by reference in its entirety into this application.

### BACKGROUND OF THE INVENTION

1. Field of the Invention

The present invention relates to a cell device and a cell string for high density NAND flash memory, and more particularly to a cell device and a cell string for high density NAND flash memory, in which an inversion layer is induced on a surface of a semiconductor substrate using a fringing electric field generated from a control electrode or a charge storage node so that cell devices and a cell string are operated, thus improving the miniaturizability of the memory device.

2. Description of the Prior Art

These days the demand for flash memory is rapidly increasing in the fields of home appliances and portable electronics, and flash memory is continuously required to increase in capacity. In the future, it is expected that cell devices will be miniaturized up to a scale of 20 nm.

A degree of integration of types of NAND flash memory is required to continuously increase alongside the development of information technology. The degree of integration of types of NAND flash memory largely depends on the degree of integration of cell devices. Recently, a length of a gate of a cell device has decreased to 50 nm or less, and capacity of the memory has reached tens of gigabytes. To follow this trend, Samsung Electronics introduced a multi-level cell which is intended to realize high coupling effect and reduced cross-talk by employing a conventional floating gate (U-shaped floating-poly cell for MLC (multi-level cell) NAND flash memory devices, at the 13^{th} Korean Conference on Semiconductors, p. 103, 2006). However, in order to manufacture the U-shaped floating-poly electrode, a pitch in a direction of channel width reaches about 100 nm or greater, thus causing a problem in the miniaturization of the cell. Furthermore, the U-shaped structure and a conventional structure exhibit a severe short channel effect because of the miniaturization when the length of a gate is about 45 nm or less. Meanwhile, although demands for a multi-level cell are increasing, it is expected that the realization of the multi-level cell will encounter great difficulties because the severe short channel effect caused by the miniaturization of cell devices results in expansion of the threshold voltage distribution. To improve the degree of integration by continuously reducing the length of a gate, alternatives must be considered. Various types of research have been carried in order to improve the degree of integration of cells having the conventional floating-poly electrodes. As a result of the research, memory cells such as FinFETs, buried channel devices and the like, which have a three-dimensional structure, and flash memory devices such as SONOS, NFGM and the like, which use nitride films or insulating storage electrodes, are being developed. These devices offer a solution which can solve the problem of the miniaturization of the conventional flash memory having floating-poly electrodes. However, these improved devices also encounter problems because the short channel effect of the devices significantly deteriorates or the miniaturization becomes impossible in the case where gates have a length of 40 nm or less.

In order to suppress the short channel effect and threshold voltage distribution which occur when a length of cell devices is decreased to 40 nm or less, Samsung Electronics introduced a SONOS (or TANOS: TaN—AlO—SiN-Oxide-Si) cell device which has an asymmetric source/drain structure in a flat channel device (by K. T. Park et al, A 64-cell NAND flash memory with asymmetric S/D structure for sub-40 nm technology and beyond, in Technical Digest of Symposium on VLSI Technology, p. 24, 2006). This device is configured such that a region corresponding to a source or a drain is provided at one side of a gate of a cell device whereas the region is not provided at the opposite side of the gate. In other words, the device is configured such that an inversion layer is induced at the region where the source or the drain is not provided by employing a fringing electric field generated from a control electrode, thus suppressing a short channel effect. This device can improve the miniaturizability to a degree, compared to a conventional SONOS cell device with a flat channel having source/drain regions. However, because the source/drain of the cell device are configured such that one of the source/drain overlaps the control electrode, the device exhibits the short channel effect in the case of a channel having a length of 40 nm or less, and eventually the miniaturization which occurs in the flat channel structure reaches a limit. In addition, one of the source/drain overlaps the control electrode, thus causing the occurrence of GIDL (Gate Induced Drain Leakage).

Furthermore, Samsung Electronics introduced a flash device structure in which a channel is recessed and a conductive floating gate is applied as a storage electrode in order to suppress the short channel effect which occurs in the conventional flat channel structure (S. -P. Sim et al, Full 3-dimensional NOR flash cell with recessed channel and cylindrical floating gate—A scaling direction for 65 nm and beyond, in Technical Digest of Symposium on VLSI Technology, p. 22, 2006). For the miniaturization of a device, the width of the recessed region must be reduced, and this causes increased resistance and non-uniformity of the device.

The present inventor proposed a cell string which comprises cell devices having no source/drain as in the present invention (Korean Patent Application No. 10-2006-0121143, entitled “High density flash memory cell string, cell device and method of manufacturing the same”). The present invention intends to propose a modification of the above patent application.

For these reasons, there is a need for development of a novel flash memory device of high density/high performance which is capable of suppressing problems occurring in the previously introduced devices such as a short channel effect and deterioration of performance caused by the miniaturization thereof.

### SUMMARY OF THE INVENTION

Accordingly, the present invention has been made keeping in mind the above problems occurring in the related art, and an object of the present invention is to provide a cell device and a cell string for flash memory which have a conventional flat channel structure and are excellent in miniaturizability and performance.

Another object of the present invention is to provide a cell device and a cell string for flash memory which are configured to increase read current and to improve device characteristics even without a source/drain.

In order to accomplish the above objects, a first aspect of the present invention provides a cell string for flash memory which includes a plurality of cell devices sequentially connected to each other and one or more switching devices disposed at ends of the plurality of cell devices to allow for selection of the cell string, in which each of the plurality of cell devices includes: a semiconductor substrate; a first semiconductor thin film disposed on the semiconductor substrate; a second semiconductor thin film disposed on the first semiconductor thin film; a permeable insulating film disposed on the second semiconductor thin film; a charge storage node, a control insulating film and a control electrode which are sequentially disposed on the permeable insulating film; and a buried insulating film disposed in the first semiconductor thin film, wherein each of the plurality of cell devices does not include source/drain regions, the first semiconductor thin film is made of semiconductor material different from that of the semiconductor substrate while the second semiconductor thin film is made of the same semiconductor material as that of the semiconductor substrate, and the charge storage node is composed of dots including nano-sized fine particles.

A second aspect of the present invention provides a cell string for flash memory which includes a plurality of cell devices sequentially connected to each other and one or more switching devices disposed at ends of the plurality of cell devices to allow for selection of the cell string, in which each of the plurality of cell devices includes: a semiconductor substrate; a permeable insulating film disposed on the semiconductor substrate; a charge storage node, a control insulating film and a control electrode which are sequentially disposed on the permeable insulating film; and a buried insulating film disposed in the semiconductor substrate, wherein the charge storage node is composed of dots including nano-sized fine particles and the cell devices do not include source and drain regions.

A third aspect of the present invention provides a cell string for flash memory which includes a plurality of cell devices sequentially connected to each other and one or more switching devices disposed at ends of the plurality of cell devices to allow for selection of the cell string, in which each of the plurality of cell devices includes: a semiconductor substrate; a first semiconductor thin film disposed on the semiconductor substrate; a second semiconductor thin film disposed on the first semiconductor thin film; a permeable insulating film disposed on the second semiconductor thin film; a charge storage node, a control insulating film and a control electrode which are sequentially disposed on the permeable insulating film; source and drain regions disposed on a surface of the second semiconductor thin film; and a buried insulating film disposed in the first semiconductor thin film between adjacent cell devices and under the source and drain regions, wherein the first semiconductor thin film is made of semiconductor material different from that of the semiconductor substrate while the second semiconductor thin film is made of the same semiconductor material as that of the semiconductor substrate, the charge storage node is composed of dots including nano-sized fine particles, and the source and drain regions are configured so as not to overlap the control electrode.

A fourth aspect of the present invention provides a cell string for flash memory which includes a plurality of cell devices sequentially connected to each other and one or more switching devices disposed at ends of the plurality of cell devices to allow for selection of the cell string, in which each of the plurality of cell devices includes: a semiconductor substrate; a permeable insulating film disposed on the semiconductor substrate; a charge storage node and a control insulating film which are sequentially disposed on the permeable insulating film; a control electrode disposed on the control insulating film; source and drain regions disposed on a surface of the semiconductor substrate; and a buried insulating film disposed in the semiconductor substrate between adjacent cell devices and under the source and drain regions, wherein the charge storage node is composed of dots including nano-sized fine particles, and the source and drain regions are configured so as not to overlap the control electrode.

In the cell string for flash memory according to the first to fourth aspects of the present invention, a gate insulating film disposed under the control electrode of the switching device may comprise the permeable insulating film, the charge storage node and the control insulating film which are identical to those of the cell device, and may be composed of a single or multi-layered insulating film.

In the cell string for flash memory according to the first to fourth aspects, the permeable insulating film may be composed of a single or multi-layered insulating film. When the permeable insulating film is composed of a multi-layered insulating film, the adjacent layers may be made of materials having different dielectric constants or band gaps.

In the cell string for flash memory according to the first to fourth aspects, nano-sized dots constituting the charge storage node may be composed of any one selected from among Si, Ge, SiGe, compound semiconductor, and metal, metal oxide and metal nitride which are of a single or more species, and the charge storage node may be composed of a single layer or a plurality of layers. When the charge storage node is composed of a plurality of layers, the adjacent layers may be separated from each other by thin insulating layers disposed therebetween. In other words, in order to form one charge storage node on another charge storage node composed of nano-sized particles, it is necessary to electrically separate the two charge storage nodes from each other.

In the cell string for flash memory according to the first to fourth aspects, the control insulating film may be composed of a single or multi-layered insulating film. When the control insulating film is composed of a multi-layered insulating film, the adjacent layers may be made of materials having different dielectric constants or band gaps.

In the cell string for flash memory according to the first to fourth aspects, the control electrode may be composed of a single or multi-layered conductive material. When the control electrode is composed of a multi-layered conductive material, the adjacent layers may be made of materials having different work functions.

The control electrode may include one or more selected from among Si, poly-Si, poly-Ge, poly-SiGe, amorphous Si, amorphous Ge, amorphous SiGe, metal oxide, metal, metal nitride and silicide which are doped at a high concentration.

In the cell string for flash memory according to the first to fourth aspects, a doping concentration of a channel formed under the control electrode may be higher than that of the remaining regions except for that of the channel.

In the cell string for flash memory according to the first to fourth aspects, a single crystal semiconductor thin film may be formed on the buried insulating film, and a thickness of the single crystal semiconductor thin film may be within a range of from 1 nm to 100 nm.

### BRIEF DESCRIPTION OF THE DRAWINGS

The above and other objects, features and advantages of the present invention will be more clearly understood from the following detailed description taken in conjunction with the accompanying drawings, in which:

FIG. 1a is a cross-sectional view showing cell devices and a cell string for flash memory cell according to a first embodiment of the present invention, in which a source/drain in a switching device disposed at a periphery of the cell string are configured so as not to overlap a control electrode;

FIG. 1b is a cross-sectional view showing cell devices and a cell string for flash memory cell according to a modification of the first embodiment of the present invention, in which the source/drain are configured so as to overlap the control electrode;

FIG. 2a is a cross-sectional view showing cell devices and a cell string for flash memory cell according to a second embodiment of the present invention, in which the source/drain in a switching device disposed at a periphery of the cell string are configured so as not to overlap a control electrode;

FIG. 2b is a cross-sectional view showing cell devices and a cell string for flash memory cell according to a modification of the second embodiment of the present invention, in which the source/drain are configured so as to overlap the control electrode;

FIG. 3a is an enlarged cross-sectional view of some cell devices of the cell string shown in FIG. la;

FIG. 3b is an enlarged cross-sectional view of some cell devices of the cell string shown in FIG. 2a;

FIG. 4a is a cross-sectional view showing cell devices and a cell string for flash memory cell according to a third embodiment of the present invention, in which a source/drain in a switching device which are disposed at the side opposite to the side connected to the adjacent cell device are configured so as not to overlap a gate electrode or a control electrode;

FIG. 4b is a cross-sectional view showing cell devices and a cell string for flash memory cell according to a modification of the third embodiment of the present invention, in which the source/drain are configured so as to overlap the gate electrode or the control electrode;

FIG. 5a is an enlarged plan view of the cell string and word lines of the device shown in FIG. 1a, which are arranged into a 2×2 array;

FIG. 5b is a cross-sectional view taken in a direction of the word line of FIG. 5a;

FIG. 5c is a cross-sectional view taken in a direction of the cell string of FIG. 5a;

FIG. 6a is a cross-sectional view showing cell devices and a cell string for flash memory cell according to a fourth embodiment of the present invention;

FIG. 6b is a cross-sectional view showing cell devices and a cell string for flash memory cell according to a modification of the fourth embodiment of the present invention;

FIG. 7a is a cross-sectional view showing cell devices and a cell string for flash memory cell according to a fifth embodiment of the present invention, in which the source/drain in a switching device are disposed at the side opposite to the side connected to the adjacent cell device and are configured so as not to overlap a gate electrode or a control electrode; and

FIG. 7b is a cross-sectional view showing cell devices and a cell string for flash memory cell according to a modification of the fifth embodiment of the present invention, in which the source/drain are configured so as to overlap the gate electrode or the control electrode.

### DETAILED DESCRIPTION OF THE INVENTION

This invention will be described in further detail by way of example with reference to the accompanying drawings.

### FIRST EMBODIMENT

Hereinafter, configuration and operation of a cell string for high density NAND flash memory according to a first embodiment of the present invention is described in detail with reference to the accompanying drawings. In the drawings, an insulating layer, a contact, metal wiring and the like are not shown for the clear illustration of principal features of the present invention.

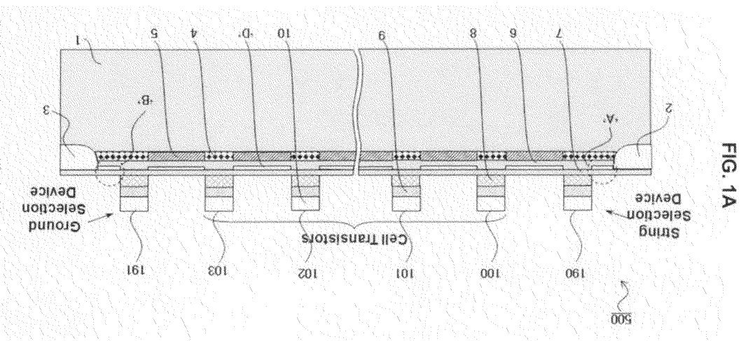

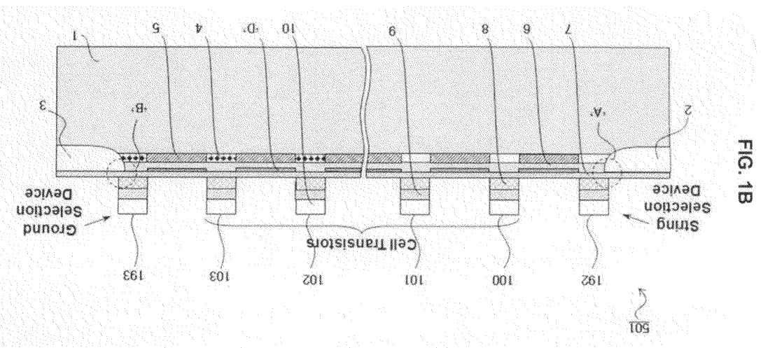

FIGS. 1a and 1b show cross-sectional views of the cell string for NAND flash memory according to the first embodiment of the present invention. Referring to FIG. 1a, the cell string for NAND flash memory 500 according to the first embodiment of the present invention includes a plurality of cell transistors 100, 101, 102, 103, a first switching device 190 and a second switching device 191. In other words, the cell string 500 comprises the plurality of cell transistors which are sequentially connected to each other, and one or more switching devices disposed at ends of the sequentially-connected cell transistors to allow for selection of the cell string. Each of the cell transistors includes a semiconductor substrate 1, a first semiconductor thin film 4 formed on the semiconductor substrate 1, a second semiconductor thin film 6 formed on the first semiconductor thin film 6, a permeable insulating film 7 formed on the second semiconductor thin film 6, a charge storage node 8, a control insulating film 9 and a control electrode 10 which are sequentially formed on the permeable insulating film 7, and a buried insulating film 5 formed in the first semiconductor thin film 4 between the cell transistors. The cell transistors include neither a source region nor a drain source, the first semiconductor thin film 4 is made of material different from that of the semiconductor substrate, and the second semiconductor thin film 6 is made of the same material as that of the semiconductor substrate.

Referring to FIG. 1b, a cell string for flash memory 501 according to a modification of the first embodiment of the present invention includes a plurality of cell transistors 100, 101, 102, 103, a first switching device 192 and a second switching device 193. The difference between the cell string 500 and 501 shown in FIGS. 1a and 1b resides in the switching devices. In the embodiment shown in FIG. 1a, none of the switching devices 190, 191 include a source or drain region disposed at the side connected to the adjacent cell transistor, and a source or drain region, which is disposed at the side opposite to the side connected to the adjacent cell transistor, is configured so as not to overlap a control electrode as indicated by the dotted circles ‘A’ and ‘B’.

In the embodiment shown in FIG. 1b, each of the switching devices 192, 193 does not include a source or drain region disposed at the side connected to the adjacent cell transistor, and a source or drain region, which is disposed at the side opposite to the side connected to the adjacent cell transistor, is configured so as to overlap a control electrode as indicated by the dotted circles “A” and “B”. In the embodiments shown in FIGS. 1a and 1b, the semiconductor substrate 1 includes the first semiconductor thin film 4; i.e., a SiGe layer and the buried insulating film 5 formed on the surface thereof. Disposed on these films is the second semiconductor thin film 6 that is preferably made of a silicon thin film. An inversion layer, which is indicated by the character “D”, is induced by the fringing electric field generated from a lateral side of the control electrode 10 when an electrical voltage for readout is applied to the control electrode 10. If the charge storage node 8 is composed of conductive material, the voltage of the control electrode 10 is coupled to the charge storage node so that the fringing electric field may be generated from a lateral side of the charge storage node thus contributing to the induction of the inversion layer D. The inversion layer D may play a role as the source/drain region in the operation of the flash memory. In a conventional cell string, source/drain regions are disposed on a semiconductor between adjacent cells or between adjacent control electrodes 10 such that they overlap the control electrodes. The miniaturization of the device can be greatly improved by eliminating the source/drain regions and allowing the induced inversion layer D to act as the source/drain regions. In addition to this, the dispersive property of the device can be reduced. In particular, the buried insulating film 5 formed on the semiconductor substrate 1 between the adjacent cells or between the adjacent control electrodes 10 enables easy formation of the inversion layer so as to greatly increase current when it is required to allow current to flow through the cell string. When the cell transistors and the-switching devices are composed of an n-type MOSFET, positive interface charges present on the interface between the buried insulating film and the semiconductor substrate make induction of the inversion layer easier. The second semiconductor thin film 6 decreases doping and thus increases mobility of a carrier in a channel, so that high current can flow when all the cell transistors are turned on. In FIG. 1, the charge storage node 8 is composed of nano-sized dots having a diameter of 20 nm or less.

### SECOND EMBODIMENT

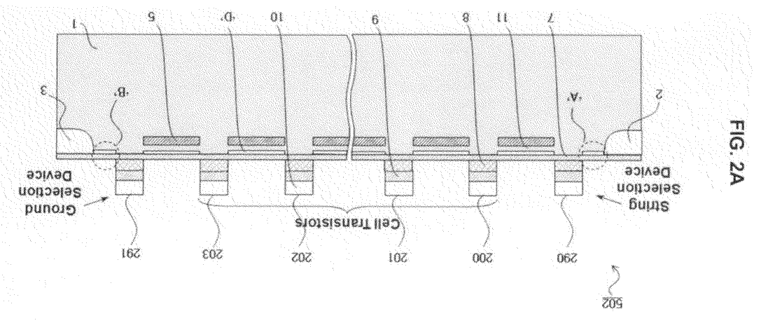

FIGS. 2a and 2b are cross-sectional views showing cell strings according to a second embodiment of the present invention, which are configured to be similar to those of the first embodiment shown in FIGS. 1a and 1b.

Referring to FIG. 2a, a cell string 502 according to the second embodiment of the present invention comprises a plurality of cell transistors which are sequentially connected to each other, and one or more switching devices disposed at ends of the sequentially connected cell transistors to allow for selection of the cell string. Each of the cell transistors includes a semiconductor substrate 1, a permeable insulating film 7 formed on the semiconductor substrate 1, a charge storage node 8, a control insulating film 9 and a control electrode 10 which are sequentially formed on the permeable insulating film 7, and a buried insulating film 5 formed in the semiconductor substrate 1 between the cell transistors.

The charge storage node 8 is composed of nano-sized dots. In this embodiment, none of the cell transistors include source and drain regions.

In the embodiment shown in FIG. 2a, each of the switching devices 290, 291 is configured such that a source or drain region disposed at the side of the control electrode 10 opposite to the side adjacent to the cell transistor does not overlap a control electrode. In a modification shown in FIG. 2b, each of the switching devices 292, 293 is configured such that a source or drain region disposed at the side of the control electrode 10 opposite to the side adjacent to the cell transistor overlaps a control electrode. In the embodiments shown in FIGS. 2a and 2b, the first semiconductor thin film 4, i.e. the SiGe layer shown in the embodiments FIGS. 1a and 1b, is omitted. When the device turned on, an inversion layer D is formed by the principle described in FIGS. 1a and 1b. The buried insulating film 5 enables the easy formation of the inversion layer D as explained in FIGS. 1a and 1b, so that current can greatly increase when it is required to allow current to flow through the cell string. The features of the embodiments shown in FIGS. 1a and 1b may be applied to these embodiments except for the SiGe layer which is omitted therefrom. Although presence of the SiGe layer may have an influence on electrical or processing properties, it does not have a major influence on the features of the present invention. In particular, since the SiGe layer is preferentially susceptible to etching compared to a silicon layer in a manufacturing process, the buried insulating film 5 can be efficiently embodied using this property.

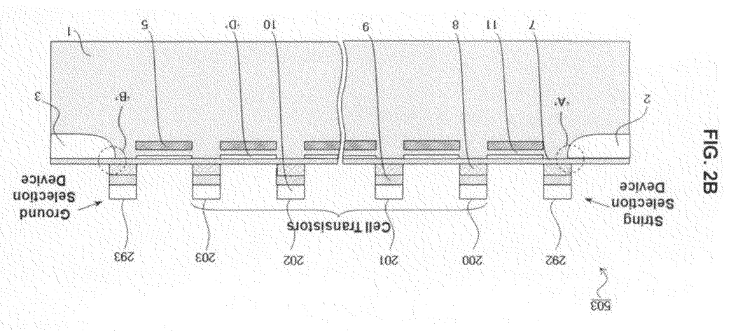

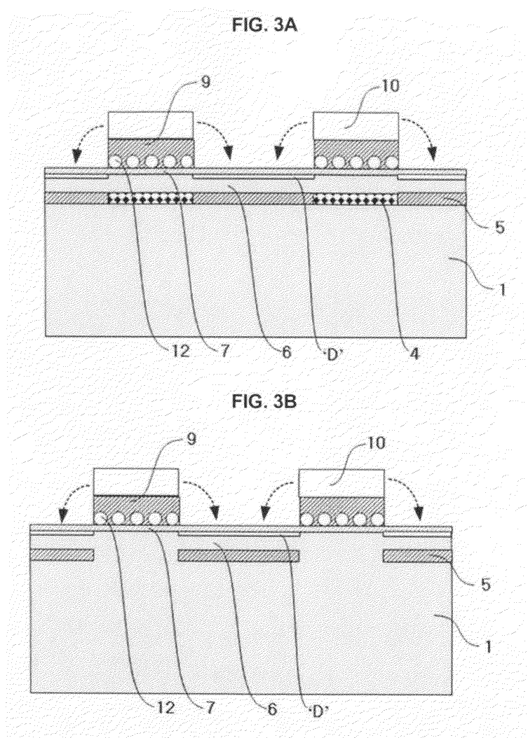

Hereinafter, the configurations and operations of the above-mentioned first and second embodiments are described with reference to FIGS. 3a and 3b. FIGS. 3a and 3b show cross sections of two cell transistors shown in FIGS. 1a to 2b. Dotted arrows in FIGS. 3a and 3b indicate the fringing electric field generated from lateral sides of the control electrodes 10 and the charge storage nodes 8. Description of the cell string may be replaced with the description disclosed with reference to FIGS. 1a to 2b. The charge storage nodes 8 are composed of nano-sized particles 12. The inversion layer D is induced on the semiconductor substrates due to a fringing electric field generated from lateral sides of the control electrodes 10 and the charge storage nodes 8 made of the fine particles 12.

### THIRD EMBODIMENT

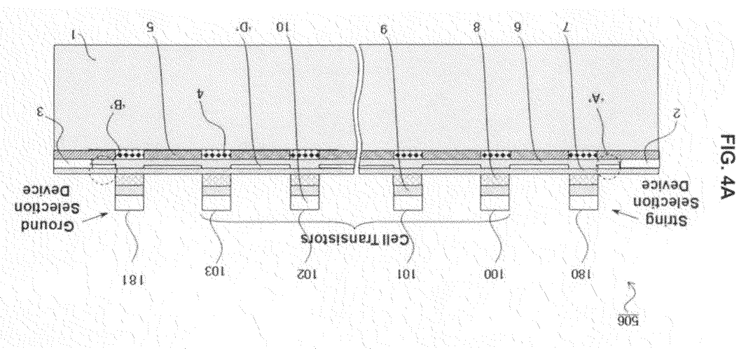

Hereinafter, a cell string according to a third embodiment of the present invention is described with reference to FIGS. 4a and 4b.

FIGS. 4a and 4b are cross-sectional views showing a cell string according to the third embodiment which is modified from cell string shown in FIGS. 1a and 1b. FIGS. 4a and 4b are views corresponding to FIGS. 1a and 1b which show the first embodiment, in which the difference between the third embodiment and the first embodiment resides in the fact that the buried insulating film 5 is formed at the side of the control electrode 10 opposite to the side adjacent to the cell transistor.

Since configuration of the cell transistor is substantially identical to the cell transistor of the first embodiment, the redundant description thereof is omitted. All switching devices 180, 181 of the third embodiment, which is shown in FIG. 4a, do not include a source or drain region disposed at the side connected to the adjacent cell transistor, and a source or drain region, which is disposed at the side opposite to the side connected to the adjacent cell transistor, is configured so as not to overlap a control electrode as indicated by the dotted circles ‘A’ and ‘B’.

FIG. 4b shows a modification of the third embodiment, in which no switching device 182, 183 includes a source or drain region disposed at the side connected to the adjacent cell transistor, and a source or drain region, which is disposed at the side opposite to the side connected to the adjacent cell transistor, is configured so as to overlap a control electrode as indicated by the dotted circles “A” and “B”.

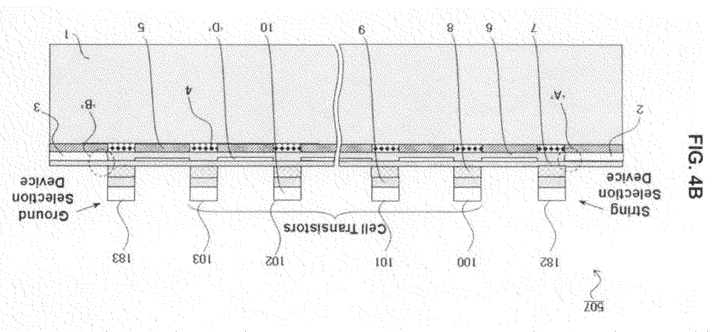

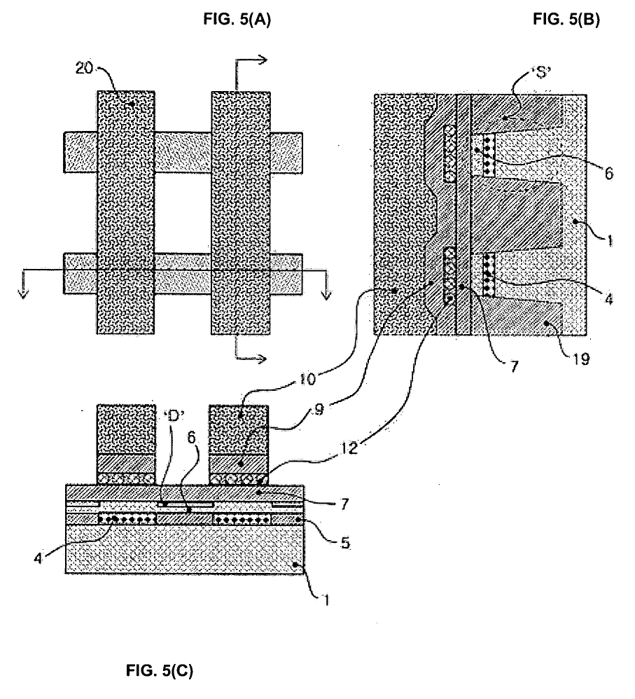

Hereinafter, body structures of the cell transistors of the cell strings according to the first and third embodiments are described with reference to FIGS. 5a to 5c.

FIGS. 5a to 5c are a plan view of a 2×2 cell array that is a part of a cell array, a cross-sectional view taken in a word line direction of FIG. 5a, and a cross-sectional view taken in a cell string direction of FIG. 5a, respectively. As shown in FIG. 5a, the word lines 20 include control electrodes 10 of respective cells connected thereto, which are oriented perpendicularly to the string. As shown in FIG. 5b which is a cross-sectional view taken in the word line direction, a charge storage node 8 is composed of nano-sized dots 12 having a diameter of 20 nm or less.

In FIG. 5b, channel regions of cell transistors and switching devices and patterned semiconductor regions between semiconductor substrates 1 constitute a body (the region indicated by a dotted ellipse ‘S’). The body may be configured such that a width of the body is uniform along its length, is continuously increased toward the semiconductor substrate 1 from the surface, or is uniform in an upper section and then continuously increases toward the lower end of the semiconductor substrate 1. Corner regions where the body meets the semiconductor substrate 1 may be shaped so as to avoid problems in the realization of the high density device, and may preferably be rounded. When the width of the body linearly or nonlinearly increases toward the semiconductor substrate 1, resistance of the body can be decreased, thus advantageously affecting an erasing operation of the NAND flash. As shown in FIG. 5b, the body is configured such that the width thereof linearly increases toward the semiconductor substrate 1. The configuration of the body may be applied to all of the cell transistors and switching devices of the present invention. The structure shown in FIG. 5c corresponds to that shown in FIG. 3a. Although FIGS. 5a to 5c are illustrated to show a plan view and cross-sectional views of the structure shown in FIGS. 1a and 1b, the structure shown in FIGS. 2a and 2b may also be illustrated to show a plan view and cross-sectional views thereof.

### FOURTH EMBODIMENT

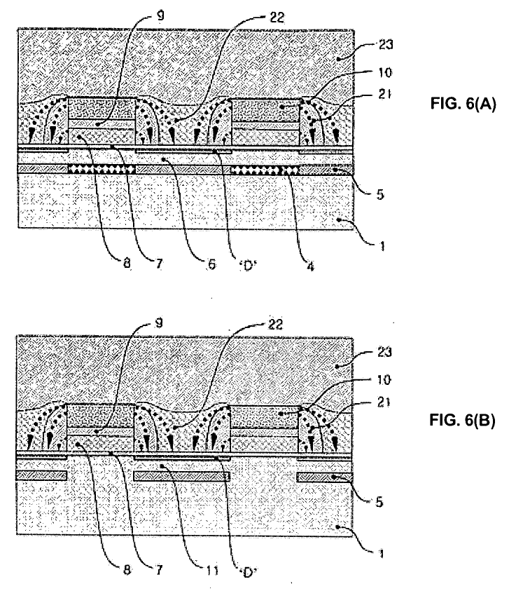

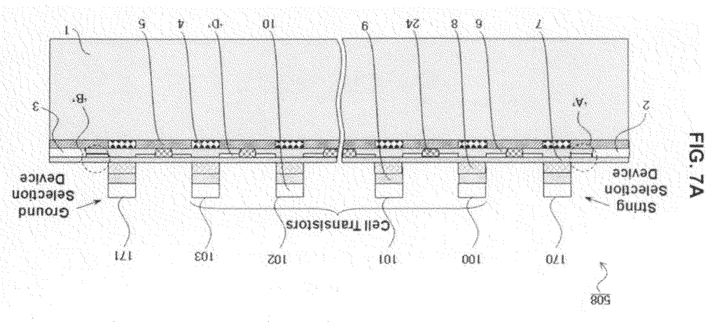

Hereinafter, a configuration of a cell string according to a fourth embodiment of the present invention is described with reference to FIG. 6. The cell string according to the fourth embodiment has a configuration in which some cell transistors are provided with additional spacers.

The cell string according to the fourth embodiment comprises a plurality of cell transistors and switching devices disposed at both sides of the plurality of cell transistors. Each of the plurality of cell transistors includes a semiconductor substrate 1, a permeable insulating film 7 formed on the semiconductor substrate 1, a charge storage node 8, a control insulating film 9 and a control electrode 10 which are sequentially formed on the permeable insulating film 7, a first semiconductor thin film 4, a second semiconductor thin film 6, buried insulating films 5 formed in the first semiconductor thin film 4 at both sides of the control electrode 10, spacers 21 formed on lateral walls of the control electrode 10, a second insulating film 22, and a third insulating film 23.

In a process of manufacturing the spacers 21 according to the fourth embodiment, after formation of the control electrodes 10 as shown in FIG. 6a, the spacers 21 are formed on lateral walls of the control electrodes 10. Subsequently, the second insulating film 22 having a high dielectric constant is formed between the cell transistors, and then the third insulating film 23 is formed throughout the entire surface of the resulting product, thus realizing the desired cell structure. Dielectric constants of the spacers 21 and the second insulating film 22 may be adjusted such that the inversion layer D is more easily induced by a fringing electric field.

FIG. 6b is a cross-sectional view showing a cell string according to a modification of the fourth embodiment of the present invention. Referring to FIG. 6b, it will be appreciated that some cell transistors of the cell string of the second embodiment shown in FIG. 2a are provided with additional spacers 21. Description of the modification shown in FIG. 6b may be substituted for by the description of the embodiment shown in FIG. 6a.

### FIFTH EMBODIMENT

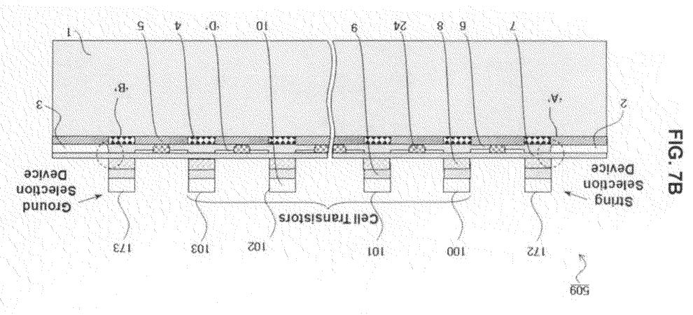

Hereinafter, configuration of a cell string according to a fifth embodiment of the present invention is described with reference to FIGS. 7a and 7b. The cell string according to the fifth embodiment of the present invention is configured such that a cell transistor includes source/drain regions which do not overlap a control electrode.

FIG. 7a shows the cell string according to the fifth embodiment of the present invention, which comprises a plurality of cell transistors and switching devices disposed at both sides of the plurality of cell transistors, and which includes the source/drain regions which are configured such that the cell transistors and the switching devices do not overlap the control electrode.

Each of the cell transistors 100, 101, 102, 103 comprises a semiconductor substrate 1, a permeable insulating film 7 formed on the semiconductor substrate 1, a charge storage node 8, a control insulating film 9 and a control electrode 10 which are sequentially formed on the permeable insulating film 7, a first semiconductor thin film 4, a second semiconductor thin film 6, a buried insulating film 5 formed in the first semiconductor thin film 4 at both sides of the control electrode 10, and a source/drain 24 formed in the second semiconductor thin film 6. A distance between the control electrode 10 and the source/drain 24 is 0.1 nm-10 nm. A junction depth of the source/drain may be within a range from 2 nm to 100 nm.

As shown in FIG. 7a, the switching devices 170, 171 include source/drain regions 2, 3 which are positioned so as not to overlap the control electrode 10. The switching devices 170, 171 are configured such that the source/drain thereof do not overlap the control electrode 10 as indicated by the dotted circles “A” and “B”.

FIG. 7b shows switching devices 172, 173 according to a modification of the fifth embodiment which are configured such that they overlap control electrodes thereof.

In the embodiments shown in FIGS. 7a and 7b, since the cell transistors are configured such that the source/drain 24 do not overlap the control electrodes, the short channel effect can be suppressed and current can easily flow when it is required to allow current to flow through the cell string.

The cell devices and the cell strings of a NAND flash memory according to the first to fifth embodiments have common features as described below.

In these switching devices, the source or the drain region 2 or 3, which is disposed at the side opposite to the side connected to the cell transistor, may be doped at a higher concentration, compared to the source/drain regions 24.

A gate insulating film disposed under the control electrode of the switching device may comprise the permeable insulating film 7, the charge storage node 8 and the control insulating film 9 which are identical to those of the cell transistor, and may be composed of a single or multi-layered insulating film.

The permeable insulating film 7 may be composed of a single or multi-layered insulating film. When the permeable insulating film 7 is composed of a multi-layered insulating film, the adjacent layers are preferably made of materials which have different dielectric constants or band gaps.

The charge storage node 8 may be embodied as nano-sized dots 12 having a diameter of 20 nm or less. The nano-sized dots 12 are composed of any one selected from among Si, Ge, SiGe, compound semiconductor, and metal, metal oxide and metal nitride which are of a single or more species. The charge storage node 8 is composed of a single layer or a plurality of layers. When the charge storage node is composed of a plurality of layers, the adjacent layers are preferably separated from each other by insulating layers disposed therebetween. Size of the nano-sized dots which constitute the charge storage node 8 may vary depending on the kind of material from which the charge storage node is made. When the nano-sized dots are made of Si or Ge, size of the nano-sized dots is preferably within a range from 1 nm to 20 nm. When the nano-sized dots are made of metal, metal oxide or metal nitride, size of the nano-sized dots is preferably within a range from 0.5 nm to 15 nm. The nano-sized dots are not limited to a particular shape, and may be of various shapes, such as a circular shape, a semicircular shape and an elliptic shape.

The control electrode 10 may be composed of a single layer or multi-layered conductive material. When the control electrode 10 is composed of a multi-layered conductive material, the adjacent layers of the control electrode are preferably made of materials having different work functions. The material from which the control electrode is made may include one or more selected from among Si, poly-Si, poly-Ge, poly-SiGe, amorphous Si, amorphous Ge, amorphous SiGe, metal oxide, metal, metal nitride and silicide which are doped into p-type or n-type.

In the cell string which includes a source/drain 24 of the cell transistor and a source or a drain of the switching device, the source and drain regions are positioned at the cell transistors and/or the switching devices. In this regard, a distance between the source and drain region and the adjacent control electrode may be within a range from 0.1 nm-100 nm, and a junction depth of the source and drain from the surface of the semiconductor substrate may be within a range from 20 nm-100 nm.

A doping concentration of the channel formed under the control electrode 10 is higher than that of regions other than the channel, thus suppressing the short channel effect.

In the cell transistors and the switching devices of the cell string, the body may be configured such that its width is uniform along the length, is continuously increased toward the semiconductor substrate 1 from the surface, or is uniform in an upper section and then continuously increased toward the lower end of the semiconductor substrate 1. Corner regions where the body meets the semiconductor substrate 1 may be shaped so as to avoid problems in realization of the high density device, and may be preferably rounded.

The semiconductor thin film 6 of single crystal is formed on the buried insulating film 5, and the semiconductor thin film may have a thickness ranging from 1 nm to 100 nm.

It is preferable that the length of the gate of the switching device or the length of the control electrode be designed to be equal to or longer than that of the cell transistor, such that the short channel effect generated from the switching device is reduced. The reason resides in the fact that a specific cell string is selected by the switching device when the short channel effect is generated from the switching device, and leak current from another cell string which is not selected may be added to the current through the selected cell string when a specific cell of the selected cell string is read out, unlike the cell transistor. This makes a precise readout of information stored in the selected cell impossible.

Hereinafter, configuration and operation of switching devices of a cell string for NAND flash memory according to another aspect of the present invention is described in detail. The cell string for NAND flash memory according to the present invention comprises a plurality of cell transistors and switching devices disposed at both sides of the plurality of switching devices. None of the switching devices includes a source or drain region disposed at the side connected to the adjacent cell transistor but each does include a source or drain region disposed only at the side opposite to the side connected to the adjacent cell transistor. In the switching device, the source or drain disposed at the side opposite to the side connected to the adjacent cell transistor is configured such that it overlaps a control electrode or it does not overlap the control electrode.

A switching device of a cell string for NAND flash memory according to still another embodiment of the present invention includes a source or drain region at the side connected to the adjacent cell transistor as well as at the side opposite to the side connected to the adjacent cell transistor, in which the source or drain region is configured so as not to overlap the control electrode.

A switching device of a cell string for NAND flash memory according to a further embodiment of the present invention includes a source or drain region at the side connected to the adjacent cell transistor as well as at the side opposite to the side connected to the adjacent cell transistor, in which the source or drain region disposed at the side connected to the adjacent cell transistor does not overlap the control electrode whereas the source or drain region disposed at the side opposite to the side connected to the adjacent cell transistor overlaps the control electrode. The remaining details of the switching device are substantially identical to the previous switching device.

In the above-mentioned several embodiments, the switching device includes a buried insulating film formed in a semiconductor region at both sides of the control electrode which overlaps or does not overlap the control electrode. More specifically, the buried insulating film may be formed in a semiconductor region at the side connected to the adjacent cell transistor or may be formed in a semiconductor region at the side opposite to the side connected to the adjacent cell transistor.

After the formation of the buried insulating film and the semiconductor thin film, the present invention may further include a step of forming an insulating spacer having a high dielectric constant on a lateral wall of the control electrode such that an inversion layer can be easily formed by a fringing electric field, or may further include a step of forming an insulating spacer on a lateral wall of the control electrode and executing an ion implantation to form source/drain regions of the cell transistor which do not overlap the control electrode.

As described above, the present invention uses dots which are composed of nano-sized fine particles instead of adopting a trap such as a nitride film as a charge storage node. As a result, the present invention has advantageous effects stemming from the fact that programming into the charge storage node and an erasing operation can be more efficiently controlled and redistribution of stored charge reduced, compared to a conventional SONOS.

According to the present invention, NAND flash memory cell transistors, which constitute one cell string, are configured to form a flat channel structure that does not have a source/drain region or that have a source/drain region overlapping the control electrode. Consequently, the gate having a length of 40 nm or less can suppress the short channel effect and thus improve the miniaturizability, compared to a conventional flat channel structure including a source/drain. The present invention has further advantages noted below.

First, the source or drain does not overlap the control or the gate electrode in the cell transistors as well as not in the switching devices for the selection of cell strings, thus improving a degree of integration of the devices and thus a degree of integration of the cell string itself.

Second, the cell transistors in the cell string according to the present invention do not include a source/drain. Even if the cell transistors have the source/drain, the source/drain does not overlap the control electrode. Consequently, GIDL (Gate Induced Drain Leakage) is relatively and considerably reduced, and thus current in an off-state can be further reduced. When there is no source/drain, leak current caused by junction between the source/drain and the substrate does not occur. Furthermore, even though the source/drain are configured to overlap the control electrode, the leak current caused by the junction is reduced because a width of the source/drain is decreased.

Third, since the present invention adopts an existing flat channel structure, development costs of memory devices can be reduced.

Fourth, an insulating layer is formed in the substrate to generate an interface charge between the insulating layer and the substrate, and thus formation of an inversion layer of a channel due to a fringing electric field by the interface charge is facilitated, thus increasing current in an on-state.

The technology of the present invention can improve the miniaturization property of a NAND flash memory device and can also improve property dispersion, thus allowing extensive application to the memory device field.

Although the preferred embodiments of the present invention have been disclosed for illustrative purposes, those skilled in the art will appreciate that the present invention is not limited thereto and that various modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A cell string for flash memory which includes a plurality of cell devices sequentially connected to each other and one or more switching devices disposed at ends of the plurality of cell devices to allow for selection of the cell string, in which each of the plurality of cell devices comprises:
a semiconductor substrate;
a first semiconductor thin film disposed on the semiconductor substrate;
a second semiconductor thin film disposed on the first semiconductor thin film;
a permeable insulating film disposed on the second semiconductor thin film;
a charge storage node, a control insulating film and a control electrode which are sequentially disposed on the permeable insulating film; and
a buried insulating film disposed in the first semiconductor thin film,
wherein each of the plurality of cell devices does not include source/drain regions,
the first semiconductor thin film is made of semiconductor material different from that of the semiconductor substrate while the second semiconductor thin film is made of the same semiconductor material as that of the semiconductor substrate, and
the charge storage node is composed of dots including nano-sized fine particles.

2. The cell string for flash memory according to claim 1, wherein the buried insulating film is disposed in the first semiconductor thin film between adjacent cell devices, or is disposed in the first semiconductor thin film under all of the plurality of cell devices of the cell string.

3. The cell string for flash memory according to claim 1, wherein each of the switching devices does not include a source or drain region at a side connected to an adjacent cell device but each does include a source or drain region at a side opposite to the side connected to the adjacent cell device, in which the source or drain region is positioned so as not to overlap the control electrode.

4. The cell string for flash memory according to claim 1, wherein each of the switching devices does not include a source or drain region at a side connected to an adjacent cell device but does include a source or drain region at a side opposite to the side connected to the adjacent cell device, in which the source or drain region is positioned so as to overlap the control electrode.

5. The cell string for flash memory according to claim 1, wherein the control electrodes of the cell devices and the switching devices are provided on lateral surfaces thereof with insulating spacers, and an insulating film is provided between the insulating spacers.

6. A cell string for flash memory which includes a plurality of cell devices sequentially connected to each other and one or more switching devices disposed at ends of the plurality of cell devices to allow for selection of the cell string, in which each of the plurality of cell devices comprises:
a semiconductor substrate;
a permeable insulating film disposed on the semiconductor substrate;
a charge storage node, a control insulating film and a control electrode which are sequentially disposed on the permeable insulating film; and
a buried insulating film disposed in the semiconductor substrate,
wherein the charge storage node is composed of dots including nano-sized fine particles and the cell devices do not include source and drain regions.

7. The cell string for flash memory according to claim 6, wherein the buried insulating film is disposed in the semiconductor substrate between adjacent cell devices, or is disposed in the semiconductor substrate under all of the plurality of cell devices of the cell string.

8. A cell string for flash memory which includes a plurality of cell devices sequentially connected to each other and one or more switching devices disposed at ends of the plurality of cell devices to allow for selection of the cell string, in which each of the plurality of cell devices comprises:
a semiconductor substrate;
a first semiconductor thin film disposed on the semiconductor substrate;
a second semiconductor thin film disposed on the first semiconductor thin film;
a permeable insulating film disposed on the second semiconductor thin film;
a charge storage node, a control insulating film and a control electrode which are sequentially disposed on the permeable insulating film;
source and drain regions disposed on a surface of the second semiconductor thin film; and
a buried insulating film disposed in the first semiconductor thin film between adjacent cell devices and under the source and drain regions,
wherein the first semiconductor thin film is made of semiconductor material different from that of the semiconductor substrate while the second semiconductor thin film is made of the same semiconductor material as that of the semiconductor substrate,
the charge storage node is composed of dots including nano-sized fine particles, and
the source and drain regions are configured so as not to overlap the control electrode.

9. The cell string for flash memory according to claim 8, wherein source and drain regions of the switching devices are configured so as not to overlap the control electrode of the switching devices.

10. The cell string for flash memory according to claim 8, wherein a source or drain region of each of the switching devices, which is disposed at a side connected to an adjacent cell device, is configured so as not to overlap the control electrode of the switching device while a source or drain region of the switching device, which is disposed at a side opposite to the side connected to the adjacent cell device, is configured so as to overlap the control electrode of the switching device.

11. The cell string for flash memory according to claim 8, wherein source and drain regions of the switching devices are doped at a higher concentration than that of the source and drain regions of the cell devices.

12. A cell string for flash memory which includes a plurality of cell devices sequentially connected to each other and one or more switching devices disposed at ends of the plurality of cell devices to allow for selection of the cell string, in which each of the plurality of cell devices comprises:
a semiconductor substrate;
a permeable insulating film disposed on the semiconductor substrate;
a charge storage node and a control insulating film which are sequentially disposed on the permeable insulating film;
a control electrode disposed on the control insulating film;
source and drain regions disposed on a surface of the semiconductor substrate; and
a buried insulating film disposed in the semiconductor substrate between adjacent cell devices and under the source and drain regions,
wherein the charge storage node is composed of dots including nano-sized fine particles, and
the source and drain regions are configured so as not to overlap the control electrode.

13. The cell string for flash memory according to claim 12, wherein source and drain regions of the switching devices are configured so as not to overlap the control electrode of the switching devices.

14. The cell string for flash memory according to claim 12, wherein a source or drain region of each of the switching devices, which is disposed at a side connected to an adjacent cell device, is configured so as not to overlap the control electrode of the switching device while a source or drain region of the switching device, which is disposed at a side opposite to the side connected to the adjacent cell device, is configured so as to overlap the control electrode of the switching device.

15. The cell string for flash memory according to claim 12, wherein source and drain regions of the switching devices are doped at a higher concentration than that of the source and drain regions of the cell devices.
